(19) United States
(12) Patent Application Publication
(10) Pub. No.: US 2025/0273383 A1
(43) Pub. Date: Aug. 28, 2025

(54) PLANAR TRANSFORMER AND DUAL ACTIVE BRIDGE

(71) Applicant: MISSION POWER CORP., Potsdam, NY (US)

(72) Inventors: RUSSEL MARVIN, Potsdam, NY (US); MATTHEW HONICKMAN, Potsdam, NY (US)

(21) Appl. No.: 18/680,030

(22) Filed: May 31, 2024

Related U.S. Application Data
(63) Continuation of application No. 18/585,173, filed on Feb. 23, 2024.

(51) Int. Cl. H01F 27/28; H01F 27/24; H05K 1/16

(52) U.S. Cl. CPC H01F 27/2804; H01F 27/24; H05K 1/165; H05K 2201/086

(57) ABSTRACT

A planar transformer includes a primary winding having one or more PCBs each including metallic traces. A secondary winding includes one or more PCBs having metallic traces. A ceramic electrical insulator electrically separates the primary and secondary windings. A magnetic core extends entirely around the windings and the electrical insulator.

### RELATED APPLICATIONS

This application is a continuation of U.S. application Ser. No. 18/585,173, filed Feb. 23, 2024, the entirety of which is incorporated by reference herein.

### TECHNICAL FIELD

The present invention relates generally to transformers, and specifically to a planar, high power, medium voltage transformer and an associated dual-active bridge module.

### BACKGROUND

Medium voltage AC to DC converters can be used in electric vehicle (EV) charging stations. More specifically, medium-voltage AC to ˜1000 VDC conversion is accomplished using many identical, high-frequency transformer-based AC to DC conversion modules connected in series on the AC medium voltage side and connected in parallel on the DC side-a so-called series-in parallel-out architecture. By placing the primary windings in series and the secondary windings in parallel, a large voltage step down can be achieved with transformers that are 1:1 or nearly 1:1 turns ratio. The transformers can achieve a frequency of about 20 kHz-200 kHz.

Due to this construction, however, the eddy current and AC losses can be high. As a result, the conductors in the transformer tend to be made from LITZ wire, laminated tape or arranged in a planar transformer. LITZ wire has fine strands of conductors that are insulated from each other but can be expensive. Moreover, the insulation used with LITZ wire tends to occupy a large percentage of the winding space. Laminated tape is thin and provides wide layers of conductors separated by insulation, which is difficult to implement in standard cores because edge winding is problematic with laminated tape.

A second challenge is the high voltage isolation that is needed between the primary and secondary windings in the transformer. Because the primary windings are many different voltages and the secondary voltages are similar, significant isolation is required. This can require 30-50 kV isolation for 15 kV class systems. Further, these devices require a Basic Impulse Level (BIL) of over 100 kV. These isolation voltages require either very large creepage and clearance distances or continuous solid insulation between the layers. Additionally, there is a desire to have the conductive components for transformer cores and for cooling to be ground referenced and isolated from any of the winding voltages.

A third challenge is the minimization of parasitic resistances, capacitances, and inductances in locations that make it difficult to switch at high frequencies and that contribute to heat generation that needs to be removed and reduce efficiencies. While some inductance is necessary for Zero Voltage Switching (ZVS) operation, too much results in excess reactive current in the bus capacitors, as well as additional losses in snubbers. Capacitance within the winding makes it more challenging to achieve ZVS switching and capacitance across the ground wall increases losses in the switches, and contributes to EMI issues.

A fourth challenge is to keep the transformer cool while achieving the above three requirements. If liquid cooling or heat pipes are employed, placing metal in or near the transformer can have high eddy current losses depending on how it is arranged, how conductive the metal is, and how thick and what orientation the metal placed. Further, the transistors added on each side of the transformer have similar requirements of low parasitics, good cooling, and high isolation.

### SUMMARY

A high-frequency planar transformer construction for high-power medium-voltage applications is described. The transformer includes a magnetic core, planar windings composed of one or more printed circuit boards (PCBs), an embedded cooling tube, and insulation layers that are substantially ceramic. Further embodiments include power transistors that switch current and control power flow through the device on each of the primary and secondary sides of the transformer to implement a compact power-transfer circuit. The transistors on each side of the transformer are attached to the same PCB and share the same insulation structures as at least one of the respective transformer windings. The embedded cooling tube could also be a heat pipe. Further embodiments package the transistors as bare die in a transistor die assembly that reduces the thermal resistance between the bare die and the coolant.

In one example, a planar transformer includes a primary winding having one or more PCBs each including metallic traces. A secondary winding includes one or more PCBs having metallic traces. A ceramic electrical insulator electrically separates the primary and secondary windings. A magnetic core extends entirely around the windings and the electrical insulator.

In another example, a dual active bridge (DAB) module includes a planar transformer having a first winding and a second winding and a magnetic core. The first winding is formed as metallic traces on at least one first printed circuit board (PCB). The second winding is formed as metallic traces on at least one second PCB. The magnetic core being formed around at least a portion of the first and second PCBs. A first plurality of transistors is formed on at least one of the first PCBs to form a first stage. The first transistors are controlled to provide a first current through the first winding based on an input voltage to provide a second current in the second winding. A second plurality of transistors is formed on at least one of the second PCBs to form a second stage. The second transistors are controlled to provide an output voltage based on the second current.

In another example, a method for providing power to electric vehicles (EVs) at an EV charging station includes electrically coupling input stages of a respective plurality of dual active bridge (DAB) modules, each of the DAB modules being formed from a plurality of printed circuit boards (PCBs) and having a respective one of the input stages, a planar transformer comprising a primary winding and a secondary winding, and an output stage. The output stages of the respective DAB modules are electrically coupled, such that the DAB modules are arranged as a voltage converter circuit. An AC current is provided to the voltage converter circuit via the input stages of the DAB modules. Switches associated with the input stages of the respective DAB modules are controlled to provide a primary current through the primary winding of each of the planar transformers of each of the DAB modules to provide a secondary current in the second winding of each of the planar transformers of each of the DAB modules. Switches associated with the output stages of the respective DAB modules are controlled to provide an output voltage from each of the DAB modules based on the respective secondary current provided in the secondary winding of the planar transformer of each of the DAB modules. The output voltage is provided to each of a plurality of isolated EV chargers for the EV charging station.

In another example, a voltage converter circuit includes a plurality of dual active bridges (DABs). Each DAB has a first stage with a plurality of first switches, a second stage with a plurality of second switches, and a transformer having a first winding coupled to a least one of the first switches and a second winding coupled to at least one of the second switches. At least one of the first and second stages of a plurality of the DABs that is a proper subset of the DABs are arranged in parallel with respect to the first winding of the transformer in each of the respective plurality of the DABs, with the parallel first stages of the plurality of the DABs being arranged in series with respect to the first winding of the transformer of at least one other DAB of the DABs, or at least one of the first and second stages of a plurality of the DABs that is a proper subset of the DABs are arranged in series with respect to the second winding of the transformer in each of the respective plurality of the DABs, with the series second stages of the plurality of the DABs being arranged in parallel with respect to the second winding of the transformer of at least one other DAB of the DABs.

Other objects and advantages and a fuller understanding of the invention will be had from the following detailed description and the accompanying drawings.

### BRIEF DESCRIPTION OF THE DRAWINGS

FIG. 1 is a schematic illustration of an example dual active bridge (DAB) module having a planar transformer in accordance with an aspect of the present invention.

FIG. 2 is a perspective view of a magnetic core of the transformer.

FIG. 3 is an exploded view of printed circuit boards (PCBs) for forming primary and secondary windings of the transformer.

FIG. 4A is a perspective view of an insulating assembly for the transformer.

FIG. 4B is an exploded view of the insulating assembly of FIG. 4A.

FIG. 5 is a perspective view of a cooling structure for the transformer.

FIG. 6 is a section view taken along line 6-6 of FIG. 1.

FIG. 7 is a top view of the DAB module with components removed.

FIG. 8 is a top view of the DAB module.

FIG. 9A is a section view taken along line 9A-9A of FIG. 8.

FIG. 9B is a section view taken along line 9B-9B of FIG. 8.

FIG. 10A is a perspective view of a transistor assembly package of the DAB module.

FIG. 10B is a top view of a portion of the DAB module with an array of transistors.

FIG. 10C is a section view taken along line 10C-10C of FIG. 10B.

FIG. 11 is a schematic illustration of the DAB module enclosed in potting.

FIG. 12A is a schematic illustration of a stand-alone planar transformer.

FIG. 12B is a schematic illustration of the stand-alone transformer enclosed in potting and a case.

FIG. 13 is an example of a circuit diagram of a dual active bridge (DAB) circuit.

FIG. 14 is another example of a circuit diagram of a DAB circuit.

FIG. 15 is an example of a voltage converter circuit.

FIG. 16 is another example of an electric vehicle (EV) charging system.

### DETAILED DESCRIPTION

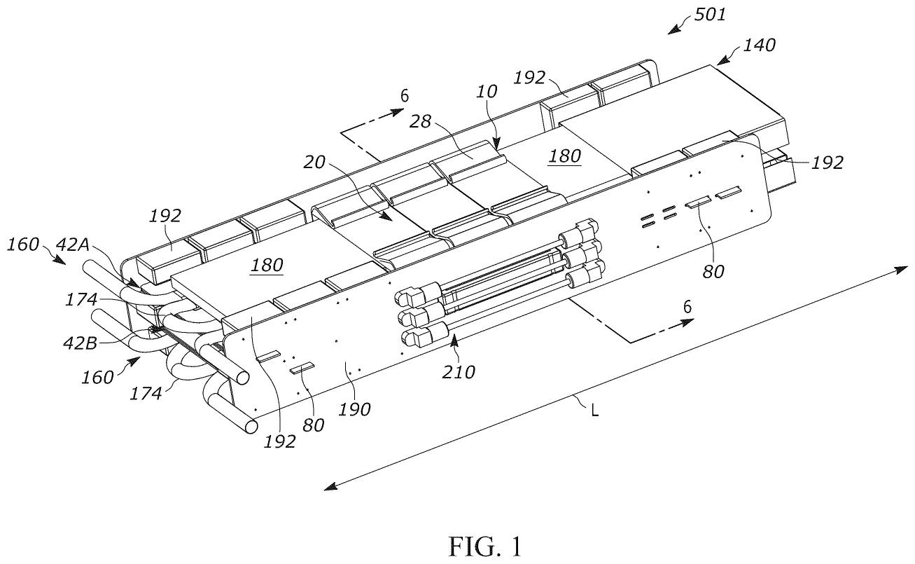

The present invention relates generally to transformers, and specifically to a planar, high power, medium voltage transformer and an associated DAB module, i.e., included in the same package assembly as a DAB module. FIGS. 1-10C illustrate an example DAB module 501 having a planar transformer 10 and extending in a direction of length L in accordance with the present invention. It is appreciated that the planar transformer 10 can alternatively be provided in other, non-DAB modules or circuits or be stand-alone, as will be described.

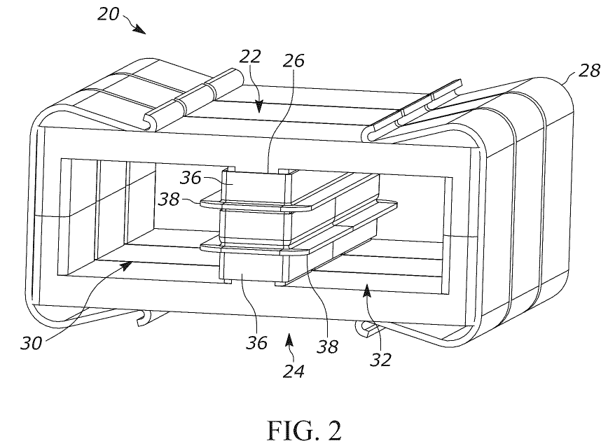

As shown in FIG. 2, the transformer 10 includes a core 20 formed from a pair of cooperating halves 22, 24. The halves 22, 24 can be configured as E-cores or E-I-cores. Regardless, the core 20 is formed from a magnetic material, such as ferrite. In one example, the core 20 is a high frequency ferrite material, such as manganese zinc ferrite, nickel zinc ferrite or other ferrite suited for an operation frequency of about 20 kHz-200 kHz.

As shown, the halves 22, 24 are E-cores that each includes a central support member 26. The support members 26 from each half 22, 24 engage one another and cooperate to define a pair of windows or passages 30, 32 in the core 20.

A pair of bobbins 36 encircle the respective support members 26 and are stacked atop one another so as to extend the entire collective height of the support members. Each bobbin 36 is generally tubular and includes a radially extending shelf or flange 38 that encircles the associated support member 26. The bobbins 36 are made from an electrically insulating material, such as nylon, silicone, PPS, PPA, PBT or polyester. The bobbins 36 should also have a Comparative Tracking Index (CTI) of greater than 600V and high temperature capability.

The core 20 shown includes three associated pairs of halves 22, 24 aligned along the length L. It will be appreciated, however, that more or fewer associated pairs of halves 22, 24 can be provided. Regardless, a compression clip 28 is provided for each associated pair of halves 22, 24 for biasing the halves towards one another. That said, three compression clips 28 are provided on the example core 20 shown. It will be appreciated that alternative/additional means could be used to secure the core 20, e.g., adhesive, tape, other fasteners, etc.

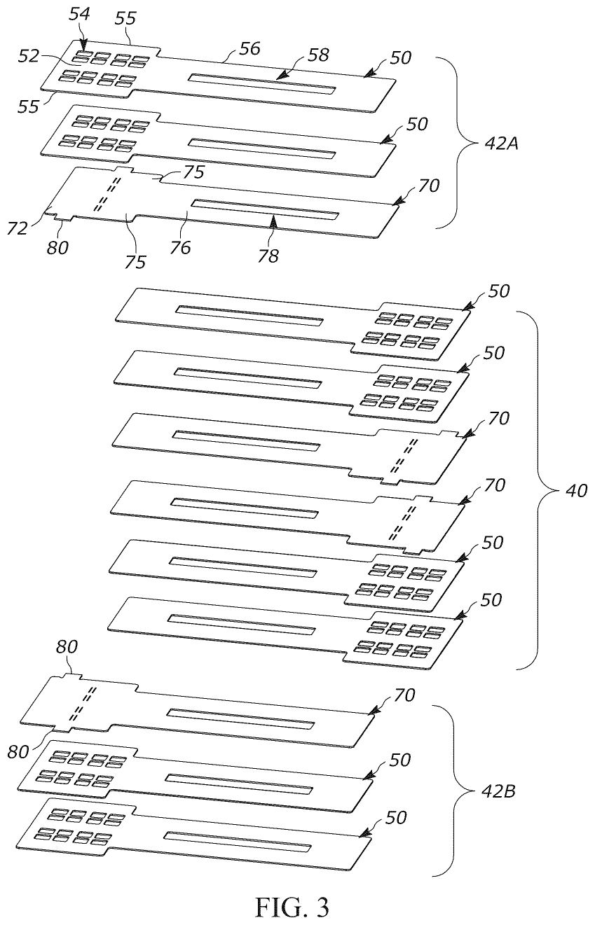

Referring to FIG. 3, the transformer 10 further includes a primary winding 40 and a secondary winding 42 formed from at least one secondary winding portion. In one example shown, a pair of secondary winding portions 42A, 42B is provided on opposite sides of the primary winding 40 and cooperate to define the secondary winding 42. In any case, each winding 40, 42 can be formed from one or more printed circuit boards (PCB) having either a first type 50 or a second type 70. In the example shown, each winding 40, 42 is formed from stacked PCBs 50, 70. It will be appreciated, however, that each PCB 50, 70 could be formed as a single layer or multiple layers and that the PCBs forming each winding 40, 42 could be single layers PCBs, multiple layer PCBs, combinations thereof, and/or combinations of PCBs having different number of layer(s) from one another within or between the windings 40, 42.

Regardless, the first PCB 50 includes a base 52 having an array of openings 54 extending through the thickness thereof. Tabs 55 extend outward from opposite sides of the base 52. A projection 56 extends longitudinally away from the base 52. An elongated opening 58 extends along the length of the projection 56 and passes entirely therethrough.

The second PCB 70 includes a base 72 and tabs 75 extending outward from opposite sides of the base. A projection 76 extends longitudinally away from the base 72. An elongated opening 78 extends along the length of the projection 76 and passes entirely therethrough. Support members 80 extend outward from opposite sides of the tabs 75.

Each PCB type 50, 70 is formed from a dielectric material. Electrical conductors or traces (not shown) are etched into a side (the top side as shown) of each PCB 50, 70 and generally encircle the respective opening 58, 78. The etched traces can extend one or more times around the respective openings 58, 78. The conductors can be made of copper or any other electrically conductive material and insulated with an epoxy-glass composite, such as FR-4. Fillers can be used in the insulation to enhance thermal conductivity.

As an example, the electrical conductors of at least one of the primary winding 40 and the secondary winding 42 can include multiple conductors arranged in parallel, such as to reduce eddy current losses. Additionally, for example, the conductor paths of the parallel conductors provided for the primary winding 40 and/or the secondary winding 42 can be transposed to link substantially equal magnetic flux of the planar transformer 10 to improve current sharing between the parallel conductors.

As shown, PCBs 50, 70 are stacked on one another to form the primary winding 40, with a pair of the PCBs 70 being sandwiched between pairs of the PCBs 50 in a six-layer construction. It will be appreciated that more or fewer of either PCBs 50, 70 can be provided to form the primary winding 40. The PCBs 50, 70 are bonded to one another with solder or sintering to form the 42A, 42B primary winding 40. Regardless, the openings 58, 78 are aligned with one another and the bases 52, 72 are aligned with one another. The PCBs 50, 70 can be bonded to one another with solder or sintering to form the primary winding 40.

Furthermore, as shown, PCBs 50, 70 are stacked on one another to form each secondary winding portion 42A, 42B, with a pair of the PCBs 50 being positioned on one side of a PCB 70 in a three-layer construction. It will be appreciated that more or fewer of either PCB 50, 70 can be provided to form the secondary winding portions 42A, 42B, but the secondary winding portions have the same configuration as one another. Regardless, the openings 58, 78 are aligned with one another and the bases 52, 72 are aligned with one another. The windings 40, 42 are oriented such that the aligned bases 52, 72 of the primary winding 40 is at an opposite end of the stack of PCBs than the aligned bases 52, 72 on both secondary winding portions 42A, 42B.

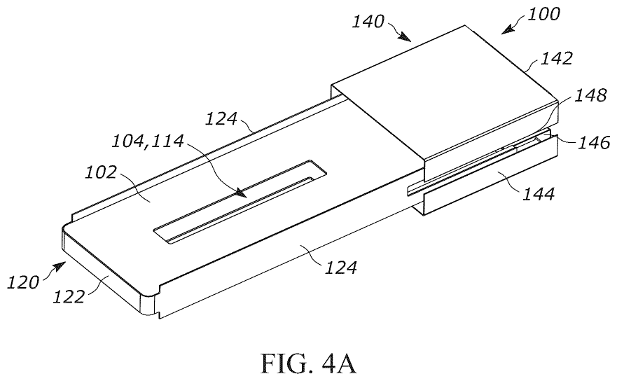

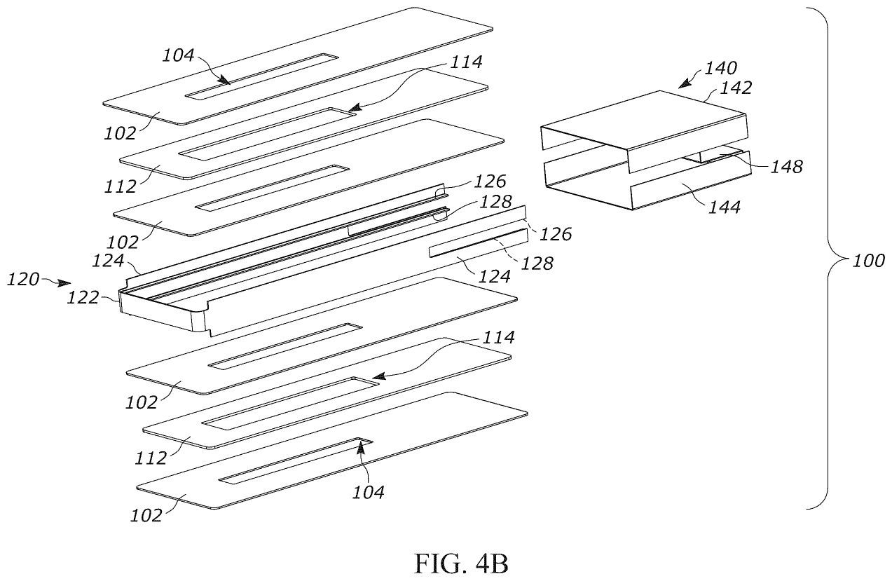

Insulation formed as an electrical insulator or insulating assembly 100 is also provided (FIGS. 4A-4B) for helping to electrically insulate the primary winding 40 from each secondary winding portion 42A, 42B. That said, components of the insulating assembly 100 are formed from an electrically insulating material, such as a ceramic. Example ceramic materials include, aluminum (III) oxide (Al₂O₃), aluminum nitride, silicon nitride, and boron nitride. As an example, the ceramic material(s) selected for the insulating assembly 100 can have dimensions that are suitable for providing a nominal operating potential between two of the electrical components, e.g., between the primary side and the secondary side of the transformer 10, of at least 2 kV.

The insulating assembly 100 includes elongated first insulating sheets 102 each having an elongated opening 104 extending along the length thereof. Second insulating sheets 112 each have an elongated opening 114 extending along the length thereof. The second insulating sheets 112 are smaller in both length and width than the first insulating sheets 102, i.e., the insulating sheets are different sizes. An edge insulator 120 has a generally U-shaped configuration and includes a base 122 and a pair of legs 124 extending therefrom parallel to one another. A pair of support rails 126, 128 extends along the entire length of the edge insulator 120 and radially inward. The support rails 126, 128 extend parallel to one another. An end cap insulator 140 has a generally box-shaped construction and includes a pair of C-shaped cover members 142, 144 connected together by a common end wall 146. A C-shaped projection 148 extends from the wall 146 into the interior between the cover members 142, 144.

When the insulating assembly 100 is assembled, two first insulating sheets 102 are positioned on opposite sides of the support rail 126 and abut both the support rail and the base 122. A single second insulating sheet 112 is positioned between the first insulating sheets 102 and within the same plane as the support rail 126. Similarly, two first insulating sheets 102 are positioned on opposite sides of the support rail 128 and abut both the support rail and the base 122.

A single second insulating sheet 112 is positioned between the first insulating sheets 102 and within the same plane as the support rail 128. This aligns all the openings 104, 114 of the sheets 102, 112 with one another. Due to this configuration, a three-piece or three-layer insulating member is associated with each rail 126, 128 and constructed from a pair of first insulating layers 102 on opposite sides of a single second insulating layer 112. The end cap insulator 140 extends over the free ends of the legs 124.

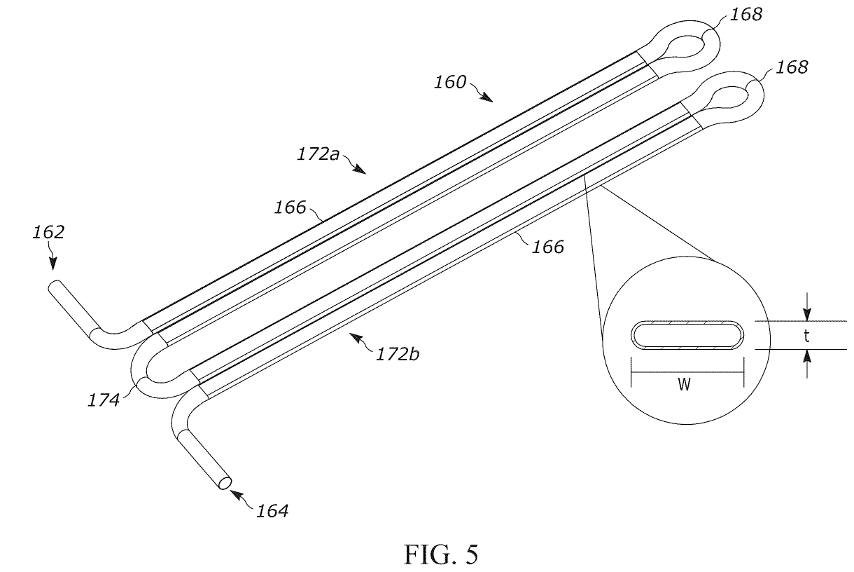

Turning to FIG. 5, a tubular cooling structure 160 extends from a first end 162 to a second end 164. Straight portions 166 extend parallel to one another and are connected at their terminal ends by curved portions 168. In one example, the straight portions 166 have flattened oval or generally rectangular cross-sections so as to increase the width (w) and decrease in thickness (t) compared to a rounder cross-section. The thickness (t) is on the order of about 0.05-1.0 mm, in particular about 0.1-0.30 mm. As will be discussed, the cooling structure 160 is configured to receive a cooling medium.

In any case, the portions 166, 168 are configured to define multiple out-and-back passes of the cooling structure 160, such as the pair of passes 172a, 172b shown. The passes 172a, 172b are connected end-to-end by a connecting portion 174. The number of passes 172 is even to position the ends 162, 164 on the same side of the cooling structure 160. The cooling structure 160 is made of metal, such as stainless steel including a 300 series or austenitic stainless steel.

It will be appreciated that the cooling structure 160 could instead be formed as a metallic, e.g., stainless steel, heat pipe. In this configuration, the heat pipe has capillary structure and a working fluid, e.g., methanol, therein that boils at approximately the working temperature of the windings 40, 42. The heat pipe can have a rounded profile or the flattened profile exhibited by the cooling structure 160 shown. The heat pipe can have the same contour/shape as the cooling structure 160 shown, i.e., multiple passes 172a, 172b, or be configured with more or fewer passes. In one example, the heat pipe includes a single straight section 166, and one or more heat pipes can extend parallel to one another through the respective passages 30, 32 in order to span a desired percentage of the width of each passage.

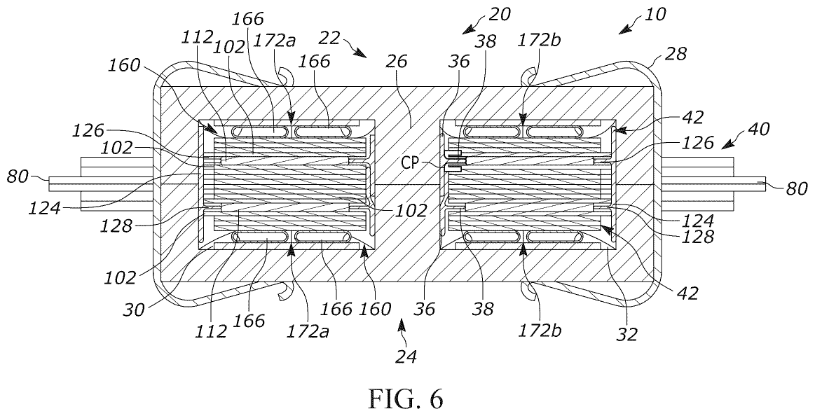

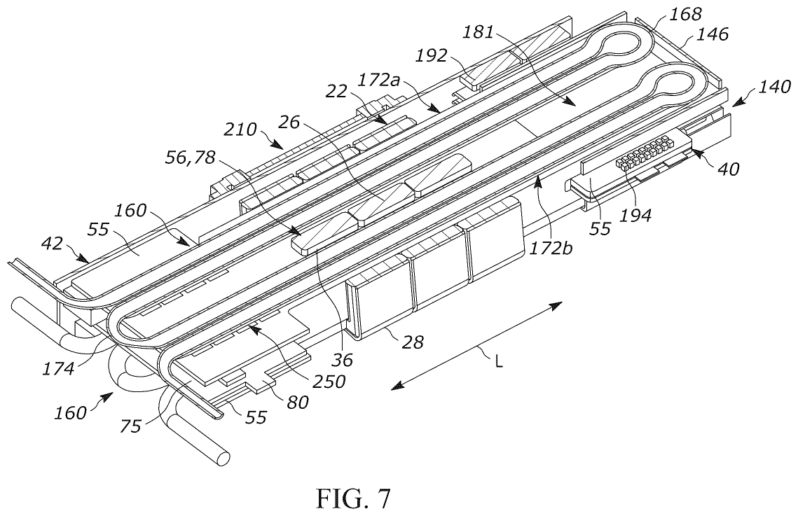

Turning to FIGS. 6-7, when the transformer 10 is assembled, the primary winding 40, secondary winding portions 42A, 42B, insulating assembly 100, and cooling structure 160 all extend through the passages 30, 32 of the core 20 in a precisely tailored manner. To this end, the legs 124 of the edge insulator 120 extend through opposite lateral sides of the passages 30, 32 and abut the interior of both halves 22, 24 of the core 20. In this manner, the support rails 126, 128 are aligned with and extend parallel to the respective shelves 38 on the bobbins 36. The insulating sheets 102, 112 extend through the core 20 with the openings 104 receiving the bobbins 36 and the openings 114 receiving the shelf 38 on each bobbin 36.

The primary winding 40 is positioned between both the shelves 38 on the bobbins 36 but also between the support rails 126, 128 on both legs 124 due to the openings 58, 78 in the PCBs 50, 70. This positions the primary winding 40 between a pair of the first insulating sheets 102. A pair of second insulating sheets 112 is provided on each side of that stack, and a second pair of first insulating sheets 102 is then provided on each side of that stack. The insulating assembly 100—in particular the sheets 102, 112—extends beyond the entire combined length of the respective secondary winding portions 42A, 42B and, thus the entire interface between the primary windings 40 and the secondary winding portions is electrically insulated.

The bases 52, 72 of the primary winding 40 extend between the cover members 142, 144 and within the end cap insulator 140. The tabs 55, 75 of the primary winding 40 extend laterally through the space between the cover members 142, 144 to positions outside the end cap insulator 140.

The secondary winding portions 42A, 42B, on the other hand, are provided outside the insulating assembly 100. One secondary winding portion 42A abuts the exterior of the outermost first insulating sheet 102 abutting the shelf 38 and the top (as shown) of the support rail 126. The other secondary winding portion 42B abuts the exterior of the outermost first insulating sheet 102 abutting the shelf 38 and the bottom (as shown) of the support rail 128. The openings 58, 78 allow the secondary winding portions 42A, 42B to exhibit this configuration. That said, the insulating assembly 100 and bobbins 36 cooperate to electrically insulate the primary and secondary windings 40, 42 from one another and electrically insulate the windings from the core 20. Furthermore, the insulating assembly 100 helps to increase the creepage distance between the primary winding 40 and each respective secondary winding portions 42A, 42B.

The cooling structures 160 are provided within the passages 30, 32 and associated with each secondary winding portion 42A, 42B. In particular, one cooling structure 160 has one pass 172a extending through the passage 30 while the other pass 172b extends through the other passage 32, with both passes being substantially in the same plane and atop the same, top (as shown) secondary winding portion 42A. Similarly, the other cooling structure 160 has one pass 172a extending through the passage 30 while the other pass 172b extends through the other passage 32, with both passes being substantially in the same plane and atop the same, bottom (as shown) secondary winding portion 42B.

Due to this construction, a single cooling structure 160 provides a back-and-forth fluid path through one passage 30 and then another back-and-forth fluid path through the other passage 32. It will be appreciated that the cooling structure 160 can be configured such that multiple, consecutive passes 172 extend through the same passage 30 and/or the passage 32. Regardless, the ends 142, 144 of the cooling structures 160 are positioned at the same end of the transformer 10.

With that in mind, the straight portions 166 of each cooling structure 160 are aligned with and extend over the array of openings 54 in the secondary winding portions 42A, 42B. As shown, straight portions 166 are in close proximity to the openings 54 in the secondary winding portions 42A, 42B with no structure therebetween. The straight portions 166 of each cooling structure 160 are also aligned with the openings 54 in the primary winding 40. The secondary winding portions 42A, 42B and insulating assembly 100—specifically the second insulating sheets 112—extend directly between the straight portions 166 and the openings 54 in the primary winding 40.

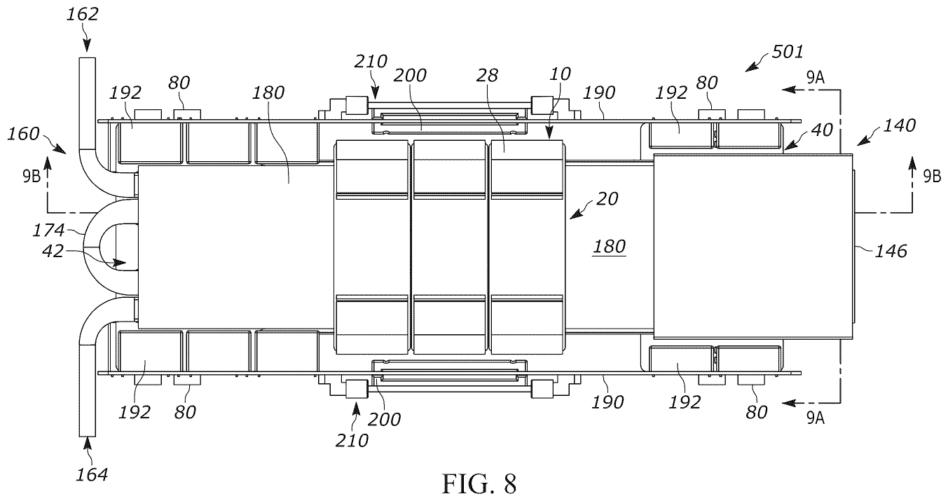

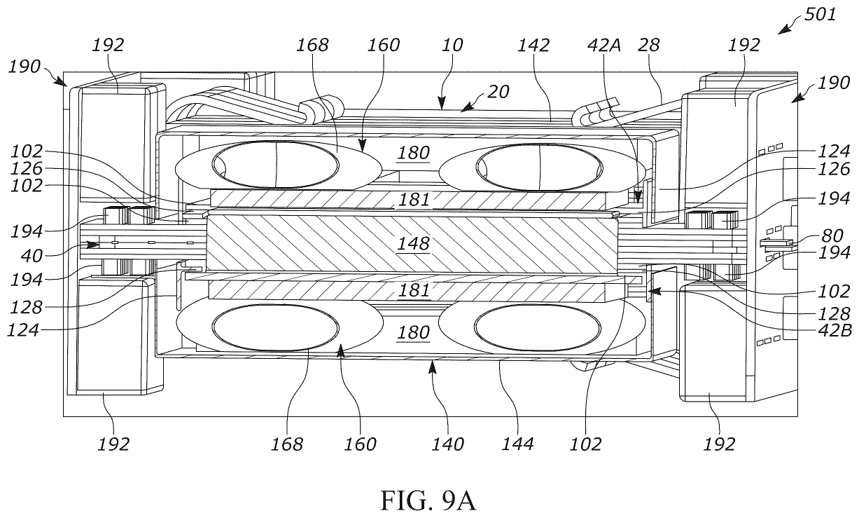

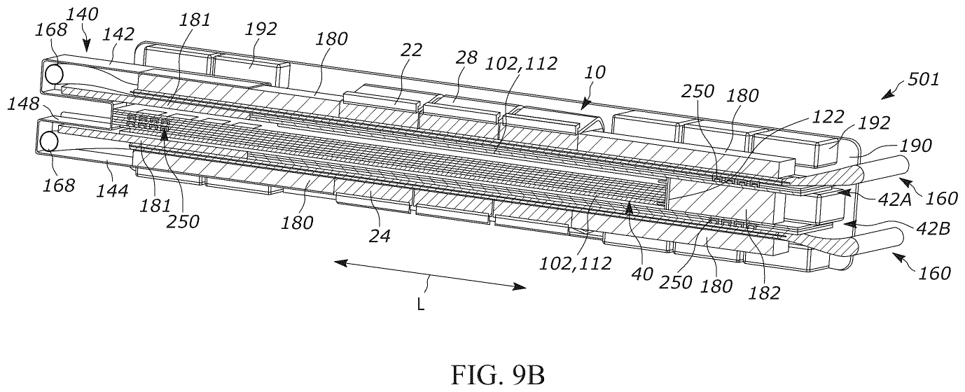

The curved portions 168 extend into the end cap insulator 140 (FIGS. 8-9B). In particular, the curved portions 168 of one cooling structure 160 are positioned on one side of the projection 148 and the curved portions 168 of the other cooling structure are positioned on the other side of the projection. In other words, the cooling structures 160 extend into the respective cover members 142, 144.

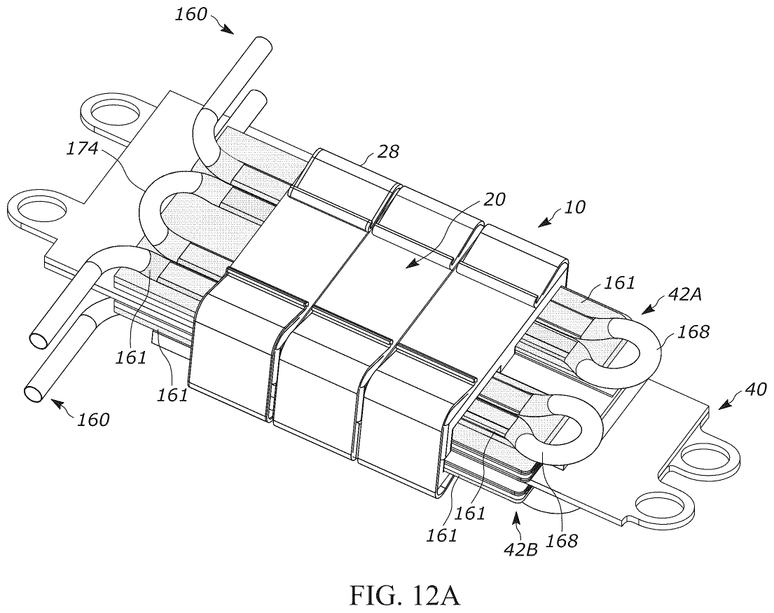

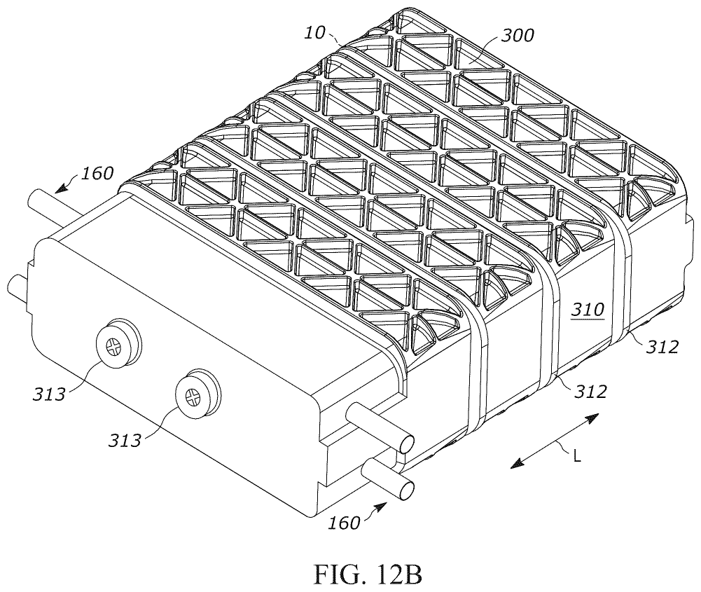

Each cooling structure 160—specifically the straight portions 166—can be electrically insulated from the associated secondary winding portions 42A, 42B with a thermal enhancement material (see 161 in FIG. 12A). The thermal enhancement material 161 can be formed from, for example, thermally conductive silicone compounds or phase change materials. It will be appreciated that in lieu of [or in addition to] the thermal enhancement material 161 the PCBs 50 adjacent the cooling structure 160 can be configured such that the copper traces thereon are provided on the side of the PCB facing away from the cooling structure. In this sense, the PCB 50 itself [or rather its thickness] acts as an insulating layer between the cooling structure 160 and secondary winding portions 42A, 42B. In any case, the clips 28 help to load the cooling structure 160 against both insulating assembly 100 as well as the core 20.

The DAB module 501 includes a transistor 250 provided in each of the aligned openings 54 within the primary winding 40 and each secondary winding portion 42A, 42B. As an example, the transistors 250 can each be provided as a metal-oxide semiconductor field effect transistor (MOSFET) having a transistor die assembly that includes one or more transistor devices. The transistors 250 can be fabricated as SiC MOSFETs, but could instead be any of a variety of different types of transistor devices, such as gallium nitride (GaN) devices, other silicon transistor devices, or silicon insulated-gate bipolar transistors (IGBTs). As an example, the transistors 250 can be either bare die components or can have a minimal surrounding package to allow a low inductance and a high thermal conductance connection to the insulating assembly 100. Background information related to an example of the transistor 250 can be found in U.S. Pat. No. 7,119,447, the entirety of which is incorporated by reference.

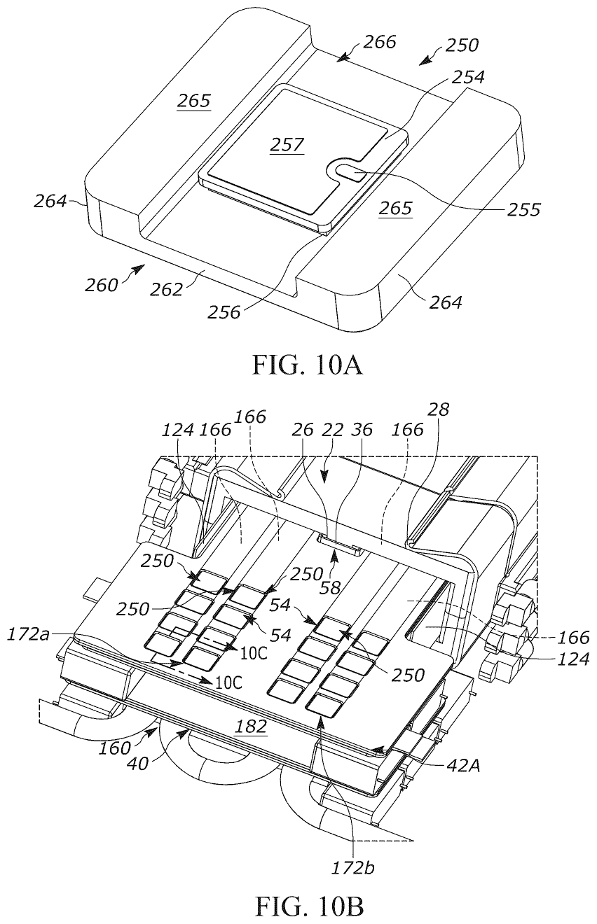

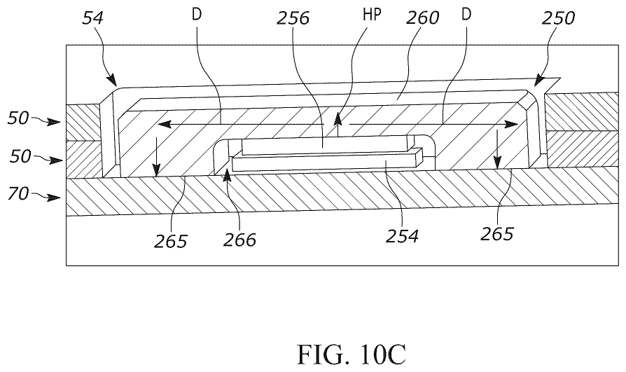

Turning to FIGS. 10A-10C, the transistor 250 shown includes an interposer 254 and a bare die 256 stacked atop one another. The bare die 256 can be formed from silicon carbide. The interposer 254 is positioned between the bare die 252 and a mounting surface, e.g., on one of the PCBs 50 and/or PCBs 70 for helping to transition the thermal coefficient of expansion and make mounting transistor 250 mounting more compatible with PCB manufacturing.

In the example of FIG. 10A, the interposer 254 includes one or more electrical vias that extend through the interposer 254 to couple a gate terminal of the bare die 252 to a gate pad 255 and to couple a source terminal of the bare die 252 to a source pad 257 for providing electrical connectivity to the associated electrical traces of the mounting surface. The interposer 254 can be made of a material having a coefficient of expansion within about 5 ppm/K of the coefficient of expansion of the transistor 250. Example materials for the interposer 254 include aluminum (III) oxide (Al₂O₃), aluminum nitride, and silicon nitride, and silicon dioxide.

The transistors 250 are incorporated into the primary and secondary windings 40, 42 on the same PCBs 50, 70 and using the single insulating assembly 100. The transistors 250 associated with the primary side of the DAB module 501 are located next to the terminals of the primary winding 40. The transistors 250 can have the same ground wall insulator to isolate the transistors 250 and connect to the transformer 10 on the same PCB 50, 70 as at least one of the primary windings 40 on the transformer 10.

A heat spreader 260 includes a base 262 and a pair of legs 264 that cooperate to define a recess 266 for receiving the interposer 254 and bare die 256. In addition, the heat spreader 260 can correspond to a drain connection for the transistor 250, such that the heat spreader is electrically connected to the drain terminal of the bare die 256, e.g., on a surface of the bare die 256 opposite the interposer 254. The heat spreader 260 is also electrically connected to the mounting surface via respective drain pads 265 arranged on the respective legs 264 and extending parallel to one another. That said, the drain pads 265 can be co-planar with one another. The heat spreader 260 can be made of a material having a coefficient of expansion within about 5 ppm/K of the coefficient of expansion of the transistor 250. Example materials for the heat spreader 260 include molybdenum, tungsten, copper-tungsten, copper-molybdenum, and aluminum-graphite. That said, the components 252, 254, 260 can be connected to one another and to the PCB 50, 70 with a sintered material made from silver or a silver alloy.

During operation, a cooling medium is supplied to the first ends 162 of the cooling structures 160. The cooling medium can be, for example, water, a water mixture, glycol, a glycol mixture or combinations thereof. An ethylene glycol or propylene glycol additive can be included to help prevent freezing and fouling. In any case, the cooling medium flows through each pass 172a, 172b in succession, passing back-and-forth through each passage 30, 32 in the core 22.

As noted, the flattened portions 166 are aligned with and in close proximity to the transistors 250 in the secondary winding portions 42A, 42B. On the other hand, heat from the primary winding 40 passes through one or more the layers of its PCBs 50, 70 and all the PCBs 50, 70 in the secondary winding portions 42A, 42B, plus the insulating assembly 100, before reaching the coolant in the cooling structures 160. Consequently, a material with a thermal conductivity greater than the thermal conductivity (˜0.25 W/m-K) for flame retardant, woven glass-reinforced epoxy resin (FR4) is selected for the PCBs 50, 70.

The cooling structures shown and described herein provide a greater thermal conduction pathway connection to the windings and core due to their flattened profile. This profile also advantageously helps to reduce the space taken up by the cooling structures in the core passages while increasing the coolant Reynolds number, thereby increasing the fluid convection coefficient. Additionally, forming the cooling structure to pass back-and-forth through the same passage allows for both the tube and the coolant therein to be electrically conductive, which reduces construction costs and helps to improve operational reliability.

A series of spacers 180, 181, 182 are provided in the DAB module 501 for helping to protect the components therein and provide a more structurally sound and compact assembly. With this in mind, a pair of spacers 180 is provided for each secondary winding portion 42A, 42B on opposite sides of the core 20, i.e., four total spacers 180 are provided. Each spacer 180 extends from the core 20 to the end of the straight portions 166 of the cooling structure 160 of that particular one of the secondary winding portions 42A, 42B. That said, the straight portions 166 are sandwiched between [but still spaced from] the outermost PCB 50 of that particular one of the secondary winding portions 42A, 42B and the spacer 180 associated therewith.

A spacer 181 (FIGS. 7 and 9B) is provided between the curved portions 168 of each secondary winding portion 42A, 42B and the end wall 146 of the end cap insulator 140. The spacers 181 extend to opposite sides of the projection 148 on the end wall 146. A spacer 182 (FIG. 10B) is also provided in the plane of the primary winding 40 and on the opposite side of the edge insulator 120 from the primary winding.

PCBs 190 are provided on both sides of the core 20 and extend along the length L of the DAB module 501 parallel to one another. The PCBs 190 receive the support members 80 extending from the tabs 75 on the primary winding 40 to secure the two together and laterally space the PCBs 190 from the secondary winding portions 42A, 42B. That said, capacitors 192 are connected to each PCB 190 on opposite lateral sides of the secondary winding portions 42A, 42B and opposite longitudinal sides of the core 20.

The PCBs 190 each include openings for receiving a second core 200 that acts as a transformer of an isolated DCDC converter to provide control and gate-drive power from the secondary side to the primary side (or vice versa). The second cores 200 are made of a ferritic material and extends to opposite sides of the PCB 190. Additional capacitors 192 are provided in the lateral space between the spacer 182 and each PCB 190. Additional capacitors 194 can be provided on the tabs 55 of the primary winding 40 (FIG. 9).

The transistors 250 associated with the primary side of the DAB module 501 are located next to the terminals of the primary winding 40. The DAB module 501 can include operating power electronics, such as including gate drive power supplies, gate driver integrated circuits (ICs), voltage and current sense circuits, and switch control signals from a controller. Because there are active components on each side of the transformer isolation barrier formed by the transformer 10, the DAB module 501 can include features for transferring power and logic signals across the isolation barrier. FIG. 8 shows one possible configuration that includes a long planar transformer core 20 to transfer power, and fiber optic links 210 between logic circuits to transfer logic signals across the isolation barrier.

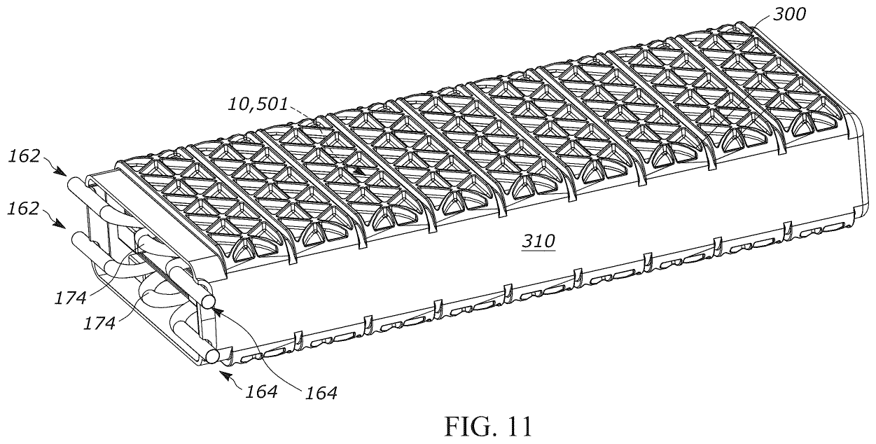

Once the transformer 10 is assembled, the entire assembly is potted in a thermally conductive, electrically insulating potting compound 300 (FIG. 11) that leaves the ends 162, 164 of the cooling structures 160 exposed/accessible. Example materials for the potting compound 300 include nylon, silicone, PPS, PPA, PBT, epoxy, or polyester. In any case, the potting compound 300 should have a low durometer (<60 Shore 00) and a low un-cured viscosity (<5000 cPs), inserted under a vacuum.

Referring to FIG. 12A, it will be appreciated that the transformer 10 can be modified to be a stand-alone assembly, i.e., one not implemented into the DAB module 501. In such a configuration, the PCBs 50, 70 are modified to omit the openings 54 for the transistors 250. Additional DAB module 501 components, such as the PCBs 190, capacitors 192, core 200, and fiber optic links 210 are also omitted. That said, the stand-alone transformer 10 can also be potted as shown in FIG. 12B.

To this end, a case 310 cooperates with the potting 300 to increase the durability of the transformer 10. The case 310 should be made of plastic, have a high temperature rating, and a high CTI greater than about 600V. The case 310 includes one or more compression clips 312 positioned along the length L of the potting 300 for providing a sustained, compressive force on the potting while also helping to mitigate any partial discharge in the potting that may occur during the life of the transformer 10. The use of silicone for the potting 300, in combination with the clips 312, can help provide a self-healing function for the transformer 10.

It will be appreciated that the case 310 can include one or more electronic couplings or connections 313 that enable the transfer of power from/between exterior of the potting 300 to the interior thereof. The connections 313 can be provided on both ends of the transformer 10/DAB module 501. That said, the connections 313 can also be provided on both ends of the case 310 shown in FIG. 11.

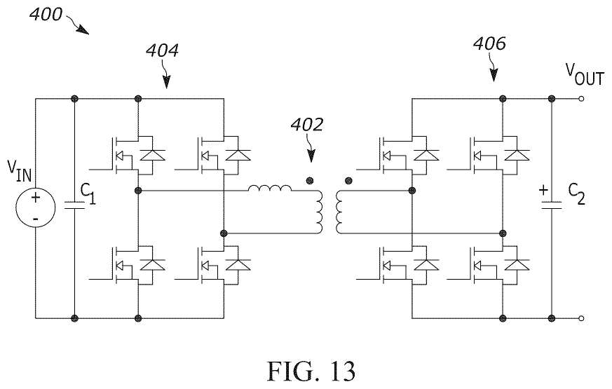

The example of FIG. 13 illustrates an example of a circuit diagram of a DAB circuit 400 associated with the transformer 10 and DAB module 501 described herein. That said, the DAB circuit 400 is demonstrated as a high-frequency DC-to-DC converter that includes a transformer 402 with a series inductor, a first stage 404 that includes a full active bridge, and a second stage 406 that likewise includes a full active bridge. In the example of FIG. 13, the transformer 402 is demonstrated as including an inductor in series with the primary winding. The inductor can be a separate inductor, or can correspond to a leakage inductance of the transformer 402 if the leakage inductance is sufficient to not require a separate inductor.

The first stage 404 is demonstrated as an input stage in which the switches of the full active bridge are switched to provide a current through the primary winding of the transformer 402 from an input voltage V_{IN} across an input capacitor C₁. Similarly, second stage 406 is demonstrated as an output stage in which the switches of the full active bridge are switched to provide an induced current through the secondary winding of the transformer 402 to provide an output voltage V_{OUT} across an output capacitor C₂. The DAB circuit 400 can be provided in a high-power voltage converter to provide for bidirectional power flow, low modulation complexity, case of resonant conversion, e.g., because it can be operated at fixed 50% duty cycle, and soft-switching, and high conversion efficiency.

The DAB circuit 400 is demonstrated in the example of FIG. 13 and described above as unidirectional. However, it is to be noted that the description of the DAB circuit 400 as converting a DC voltage at the input stage via the primary winding to provide a DC voltage at the output stage via a secondary winding is one example implementation regarding the orientation of the DAB circuit 400. As another example, the DAB circuit 400 can operate bidirectionally, such that the input stage/primary and output stage/secondary could be reversed. The potential bidirectional operation of the DAB circuit 400 can likewise be applicable to the further examples described below.

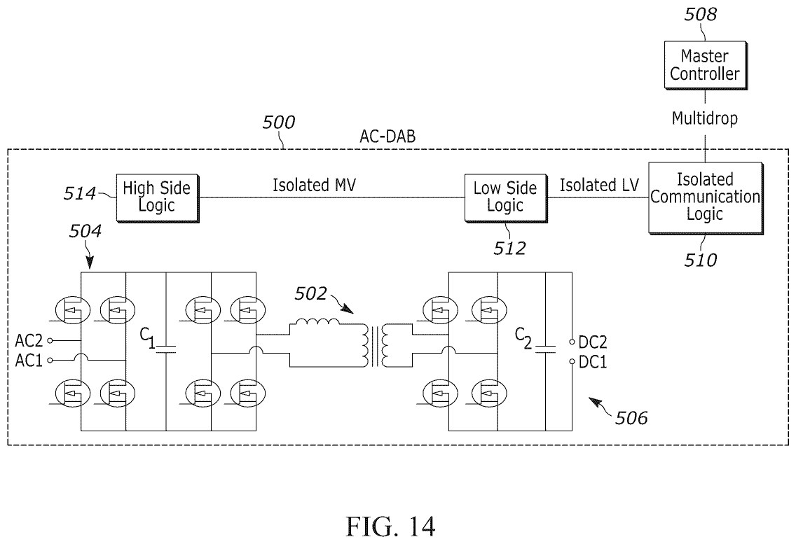

As an example, the transformer 10 can be implemented as the transformer 402 in the DAB circuit 400 to achieve high-power voltage conversion in a compact form-factor, such as the DAB module 501, as described herein. The example of FIG. 14 illustrates another example of a circuit diagram of a DAB circuit 500. The DAB circuit 500 is demonstrated similar to the DAB circuit 400 in the example of FIG. 13, and thus includes a transformer 502, a first stage 504 that includes a full active bridge, and a second stage 506 that likewise includes a full active bridge. However, the first stage 504 also includes an additional full active bridge, such that the DAB circuit 500 can provide AC-DC conversion. Similar to as described above, the transformer 10 can be implemented as the transformer 502 in the DAB circuit 500 to achieve high-power voltage conversion in a compact form-factor. Furthermore, the DAB circuit 500 can correspond to the DAB module 501 described above in the example of FIG. 1.

For example, the switches of the first and second stages 504 and 506 can correspond to the transistors 250 described above, and the capacitors C₁ and C₂ can correspond to the capacitors 190 and 192 described above. In addition, the DAB circuit 500 includes a set of controls for operating the DAB circuit 500. The controls include a master controller 508, a set of isolated communication logic 510, low-side logic 512, and high-side logic 514. As an example, the master controller 508 and/or the communication logic 510 can be external to the DAB circuit 500, and thus external to the DAB module 501, e.g., to control all DAB modules 501 in a given set of DAB modules, as described in greater detail below. The isolated communication logic 510, secondary-side logic 512, and primary-side logic 514 can be included in the DAB module 501. For example, the fiber-optic link 210 of the DAB module 501 can be implemented to provide logic signals between the primary-side logic 514 and the secondary-side logic 512.

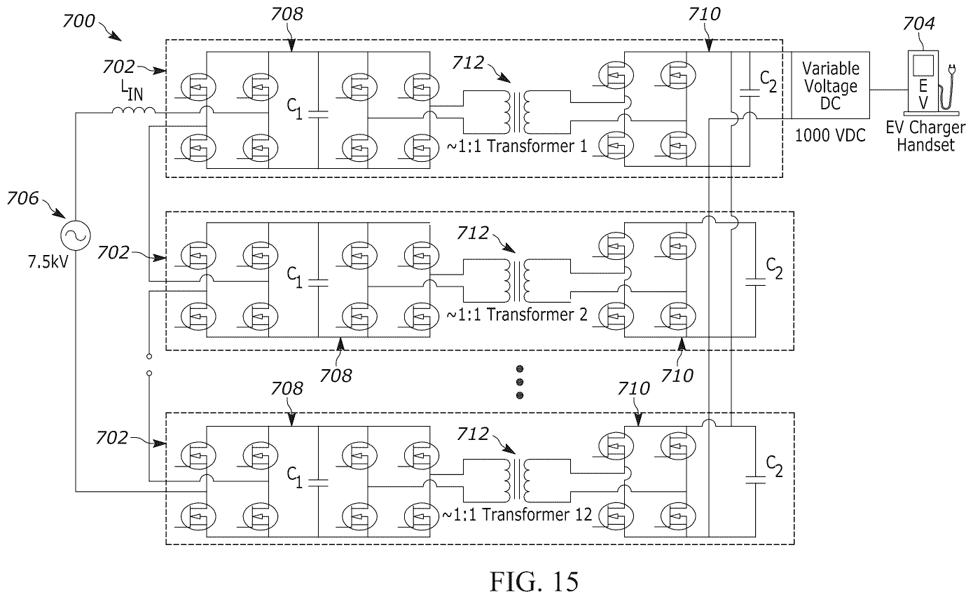

To achieve conversion of the medium amplitude AC voltage to the high amplitude DC voltage, a group of DAB circuits 500 can be electrically combined to form a voltage converter circuit. The example of FIG. 15 demonstrates a voltage converter circuit 700 that includes a plurality of DAB circuits 702, demonstrated as twelve in the example of FIG. 15, that provide voltage conversion for an EV charging station 704. As an example, each of the DAB circuits 702 can correspond to the DAB circuit 500 described above to collectively convert a medium amplitude AC voltage, such as at least 5 kVAC (e.g., 7.5 kVAC), provided from an AC input 706 to a high amplitude DC voltage, such as at least 750 VDC (e.g., 1000 VDC), provided to the EV charging station 704. Each of the DAB circuits 702 includes an input (primary) stage 708 and an output (secondary) stage 710 that are interconnected by a high-frequency transformer 712, e.g., the planar transformer 10 described above.

In the example of FIG. 15, the primary windings of the transformers 712 of each of the DAB circuits 702 are connected in series via the input stage 708, and the secondary windings of the transformers 712 of each of the DAB circuits 702 are connected in parallel via the output stage 710. As a result, the voltage converter circuit 700 exhibits a series-in parallel-out architecture. By placing the primary windings of the transformer 712 in series and the secondary windings of the transformer 712 in parallel, a large voltage step-down can be achieved using approximately 1:1 turns ratio of the transformers 712. It is noted that turns ratios other than 1:1 can instead be implemented, e.g., between approximately 0.5:1 and 2:1. This general topology allows for isolated voltage conversion without the use of large, e.g., 50 or 60 Hz, transformers. A higher transformer frequency allows for the use of smaller transformers, such as the transformer 10. Similar to as described above, while the term “primary” refers to the AC voltage side and the term “secondary” refers to the DC side, the configuration of the voltage converter circuit 700 can operate bidirectionally, such that the primary and secondary could be reversed in practice.

In the example of FIG. 15, the voltage converter circuit 700 also includes an inductor L_{IN} in series with the AC input 706, thereby rendering the front end of the voltage converter circuit 700 to act as an active boost rectifier providing the DC voltage on the capacitor C₁ in the input stage 708 of each of the DAB circuits 702. The combination of the AC-DC DAB circuits 702 having the inputs connected through the primary winding of each of the transformers 712 in series provides for a multilevel converter input stage which allows multiple lower voltage transistors to be used as the switches of the input stages 708 to accommodate a high voltage input from the AC input source 706.

For example, as described above, the transistors of the input and/or output stages 708 and 712 can be arranged as the transistors 250 of the DAB module 501. The series inductor L_{IN} for the series connected modules can make the input stages 708 of the voltage converter circuit 700 operate as a cascaded active boost rectifier. While the single inductor L_{IN} is demonstrated in the example of FIG. 15 in series with the series-connected input stages 708, an individual inductor can instead be included in the input stage 708 of each of the DAB circuits 702, and thus included in the DAB module 501, such as to provide for a more modular construction of the voltage converter circuit 700.

The voltage converter circuit 700 can each be configured in a variety of different ways to provide AC-DC conversion, DC-DC conversion, DC-AC conversion, or AC-AC conversion. For example, an additional full active bridge can be provided to the output of each of the DAB circuits 700 to provide an AC output voltage, e.g., 600 VAC, collectively. As another example, the secondary windings of the transformers 712 in the output stages 710 of the DAB circuits 700 may be coupled together in different ways in a given one of the voltage converter circuits 802. For example, for an even number of DAB modules 700, pairs of the output stages 710 of respective DAB circuits 702 can be arranged in series instead of parallel to provide twice the output voltage, e.g., 2 kV, at half the output current than the fully parallel connection shown in the example of FIG. 15.

Similarly, pairs of the input stages 708 of respective DAB circuits 702 can be arranged in parallel instead of series to provide twice the input current over a uniform AC voltage for each pair than the fully series connection shown in the example of FIG. 15. The voltage converter circuit 700 can thus be configured with any variation of AC or DC input or output, and any combination of series and parallel couplings of the input stages 708 and the output stages 710 to affect the amplitude of the output voltage V_{OUT}.

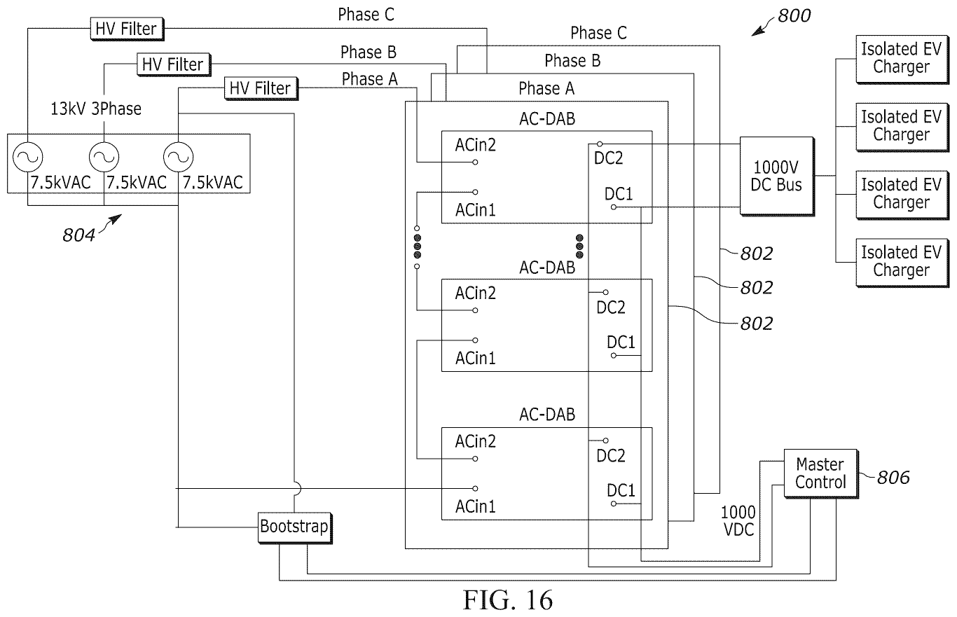

The example of FIG. 16 demonstrates another example of an EV charging system 800. The EV charging system 800 includes three separate phases of AC power, Phases A through C, that are provided to three respective voltage converter circuits 802. Each of the voltage converter circuits 802 can correspond to the voltage converter circuit 700, and can thus each include a plurality of DAB circuits 500, e.g., that each correspond to the DAB module 501. Accordingly, each of the voltage converter circuits 802 can implement the same DAB circuits 500 for each of the voltage converter circuits 802, thereby providing for a simple modular design of each of the voltage converter circuits 802.

In the example of FIG. 16, the three separate phases of AC power are provided from AC power sources 804 to provide 13 kVAC three-phase power to the three voltage converter circuits 802, such that each of the voltage converter circuits 802 can generate 1000 VDC. As an example, the 13 kVAC three-phase power can be connected in a wye configuration to provide the 7.5 kVAC to each of the voltage converter circuits 802, thus reducing the number of DAB circuits 500 in each of the respective voltage converter circuits 802. Alternatively, the 13 kVAC three-phase power can be connected in a delta configuration to provide the 13 kVAC to each of the voltage converter circuits 802.

The EV charging system 800 includes a master controller 806 that can draw sinusoidal current in phase with the source phase voltages to achieve near-unity power factor, i.e., power correction (PFC). As an example, the master controller 806 can regulate the output voltage on the capacitors C₂ of each of the DAB circuits 500, while simultaneously maintaining an approximately equal voltage across all the capacitors C₁ in each of the DAB circuits 500. Therefore, the master controller 806 can provide active voltage balancing in providing the output voltage to each of a plurality of isolated EV chargers for the EV charging system 800.

For example, the master controller 806 can control the switches of the first and second stages 504 and 506 between the capacitors C₁ and C₂ of each of the DAB circuits 500 to perform the sinusoidal current control in conjunction with regulating the voltage on the respective capacitor C₂. In the example of FIG. 16, the three phases of the AC power 804 are balanced, and all of the capacitors C₂ of each of the DAB circuits 500 are connected in parallel across the three respective power converter circuits 802. Therefore, the three balanced phases of the AC power 804 can result in minimization of the total amount of capacitance of the capacitors C₂. The cascaded AC/DC front end stages of each of the DAB circuits 500 in each of the voltage converter circuits 802 act to maintain approximately balanced and equal voltages on the capacitors C₁ by directing the input AC current in or out of each of the capacitors C₁ as needed for proper regulation.

What have been described above are examples of the present invention. It is, of course, not possible to describe every conceivable combination of components or methodologies for purposes of describing the present invention, but one of ordinary skill in the art will recognize that many further combinations and permutations of the present invention are possible. Accordingly, the present invention is intended to embrace all such alterations, modifications and variations that fall within the spirit and scope of the appended claims.

What is claimed is:

1. A planar transformer comprising:
a primary winding comprising a first series of one or more printed circuit boards (PCBs) each including metallic traces;
a secondary winding comprising a second series of one or more PCBs including metallic traces;
a ceramic electrical insulator for electrically separating the primary and secondary windings; and
a magnetic core extending around the windings and the electrical insulator.

2. The planar transformer recited in claim 1, wherein the magnetic core includes at least one passage and cooling structure filled with liquid extends back and forth through each of the at least one passage and over at least one of the windings.

3. The planar transformer recited in claim 1, wherein the core has one of an E-core and an E-I-core shape.

4. The planar transformer recited in claim 1, wherein the core comprises ferrite.

5. The planar transformer recited in claim 1, wherein the at least one first and second windings include copper.

6. The planar transformer recited in claim 1, wherein the electrical insulator has more than one layer and at least two adjacent layers have different sizes from one another.

7. The planar transformer recited in claim 1, wherein the ceramic comprises Al₂O₃ (Alumina).

8. The planar transformer recited in claim 1, wherein the ceramic comprises aluminum nitride.

9. The planar transformer recited in claim 1, wherein the ceramic comprises silicon nitride.

10. The planar transformer recited in claim 1, wherein the electrical insulator extends continuously along the entire length of an interface between the primary and secondary windings.

11. The planar transformer recited in claim 1, further comprising:
first electrical components connected to the primary winding; and
second electrical components connected to the secondary winding, wherein the electrical insulator electrically separates the first and second electrical components from one another.

12. The planar transformer recited in claim 1, wherein the PCBs are formed from a fiber-reinforced epoxy laminate.

13. The planar transformer recited in claim 1, wherein at least one of the primary winding and the secondary winding comprises a plurality of conductors arranged in parallel to provide conductor paths that are transposed to link substantially equal magnetic flux of the planar transformer.

14. The planar transformer recited in claim 1, wherein the primary winding and the secondary winding are arranged with a turns ratio between 0.5:1 and 2:1.

15. A dual-active bridge module including the transformer recited in claim 1 and at least one additional H-bridge.

16. The planar transformer recited in claim 1, wherein the core includes a central support member defining a pair of passages for receiving the primary and secondary windings, and wherein a ceramic bobbin extends around the central support member and cooperates with the electrical insulator for electrically separating the primary and secondary windings.

17. A planar transformer comprising:
a primary winding comprising a first series of one or more PCBs each including metallic traces;
a secondary winding comprising a second series of one or more PCBs each including metallic traces;
a magnetic core extending around a portion of the windings and defining at least one passage; and
cooling structure extending back and forth through each of the at least one passage and over at least one of the windings.

18. The planar transformer recited in claim 17, wherein at least one of the primary winding and the secondary winding comprises a plurality of conductors arranged in parallel to provide conductor paths that are transposed to link substantially equal magnetic flux of the planar transformer.

19. The planar transformer recited in claim 17, wherein the cooling structure comprises a metal tube with liquid coolant therein.

20. The planar transformer recited in claim 19, wherein the tube includes a flattened portion extending over the secondary winding.

21. The planar transformer recited in claim 19, wherein the liquid coolant comprises one of water and a water mixture.

22. The planar transformer recited in claim 19, wherein the liquid coolant comprises glycol.

23. The planar transformer recited in claim 17, wherein the core has one of an E-core and an E-I-core shape.

24. The planar transformer recited in claim 17, wherein the cooling structure comprises at least one sealed metallic pipe containing a capillary structure and a working fluid that boils at approximately a working temperature of the windings.

25. The planar transformer recited in claim 24, wherein the working fluid comprises methanol.

26. A dual-active bridge (DAB) circuit comprising the transformer recited in claim 17, the DAB circuit comprising a first stage coupled to the primary winding and a second stage coupled to the secondary winding, each of the first and second stages comprising at least one set of switches arranged as an H-bridge.

27. The planar transformer recited in claim 17, wherein one of the first series of stacked PCBs comprises solder pads arranged to couple to primary-side electrical components.

28. The planar transformer recited in claim 27, further comprising a ceramic insulator electrically separating the primary and secondary windings, the ceramic insulator further providing ground wall insulation between the solder pads and the primary winding.

29. The planar transformer recited in claim 17, wherein one of the second series of stacked PCBs comprises solder pads arranged to couple to secondary-side electrical components.

30. The planar transformer recited in claim 29, further comprising a ceramic insulator electrically separating the primary and secondary windings, the ceramic insulator further providing ground wall insulation between the solder pads and the secondary winding.
